(19) United States
(12) Patent Application Publication
(10) Pub. No.: US 2009/0212345 A1
(43) Pub. Date: Aug. 27, 2009

(54) Semiconductor Device and Method for Manufacturing the Same

(75) Inventor: Sung Hoon Lee, Icheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/137,135

(22) Filed: Jun. 11, 2008

(30) Foreign Application Priority Data
Feb. 21, 2008 (KR) 10-2008-0015952

(51) Int. Cl. H01L 29/00; H01L 21/3205

(52) U.S. Cl. 257/321; 438/594; 257/E29.001; 257/E21.294

(57) ABSTRACT

Disclosed herein are a semiconductor device and a method for manufacturing the same. A method of manufacturing a semiconductor device includes forming a tunnel insulating layer, a first conductive layer, a dielectric layer, a second conductive layer and a gate electrode layer on a semiconductor substrate; patterning the gate electrode layer to expose the second conductive layer; forming a protective layer on a side wall of the gate electrode layer; and etching the exposed second conductive layer, the dielectric layer, and the first conductive layer to form a gate pattern.

### CROSS-REFERENCE TO RELATED APPLICATION

The priority of Korean Patent Application No. 10-2008-0015952, filed on Feb. 21, 2008, the contents of which are incorporated herein by reference in its entirety, is claimed.

### BACKGROUND OF THE INVENTION

1. Field of the Invention

The disclosure relates generally to a semiconductor device and a method for manufacturing the same, and more particularly to a semiconductor device and a method for manufacturing the same for forming a gate pattern.

2. Brief Description of Related Technology

In general, in a flash memory device of a semiconductor device, a gate pattern is formed by patterning a conductive layer for a floating gate, a dielectric layer, a conductive layer for a control gate, and a gate electrode layer.

FIG. 1 is a sectional view of a semiconductor device for illustrating method for manufacturing a semiconductor device according to a conventional art.

Referring to FIG. 1, a tunnel insulating layer 11, a conductive layer 12 for a floating gate, a dielectric layer 13, a conductive layer 14 for a control gate, a gate electrode layer 15 and a hard mask layer 16 are formed on a semiconductor substrate 10. Then, the hard mask layer 16 is patterned and an etching process using the patterned hard mask layer is performed to pattern the gate electrode layer 15.

In general, in a semiconductor device having a thickness of 50 nm or less, if a tungsten silicide (WSiₓ) layer is used as a gate electrode layer, a resistance (Rs) of word line is increased due to a large specific resistance of the tungsten silicide layer, and so a program speed and a read ratio of the device become lowered. To solve the above problem, the thickness of the tungsten silicide layer should be increased. In forming the tungsten silicide layer, however, it is difficult to pattern the word lines, and a void can be generated in an isolation layer that electrically isolates the word lines from each other. Accordingly, a method in which a gate electrode layer is formed by using a tungsten layer having a specific resistance lower than that of the tungsten silicide layer has been studied.

However, the tungsten layer is easily oxidized through a thermal process, and is easily eroded, and then resolved by a cleaning solution in a cleaning process so that the tungsten layer imposes many restrictions on the subsequent processes.

### SUMMARY OF THE INVENTION

Disclosed herein is a method of manufacturing semiconductor device, in which an exposed surface of the gate electrode layer (i.e., side walls of the gate electrode layer) is surrounded with the protective layer, after patterning the gate electrode layer in a process forming the gate pattern, so that it is possible to prevent the gate electrode layer from being oxidized during subsequent thermal, cleaning, and etching processes.

Also disclosed herein is a semiconductor device in which an exposed surface of the gate electrode layer (i.e., side walls of the gate electrode layer) is surrounded with the protective layer to prevent the gate electrode layer from being oxidized during subsequent processing.

An embodiment of the device includes a tunnel insulating layer, a conductive layer for a floating gate, a dielectric layer, a conductive layer for a control gate and a gate electrode layer formed on a semiconductor substrate; and a protective layer formed on a side wall of the gate electrode layer.

The protective layer preferably is a nitride layer. The protective layer may also include an oxide layer. The nitride layer preferably has a thickness of 20 Å to 100 Å, and the oxide layer preferably has a thickness of 20 Å to 150 Å. The gate electrode layer preferably is formed from tungsten (W).

The method for manufacturing a semiconductor device according to one embodiment of the invention includes forming a tunnel insulating layer, a first conductive layer, a dielectric layer, a second conductive layer, and a gate electrode layer on a semiconductor substrate; patterning the gate electrode layer to expose the second conductive layer; forming a protective layer on a side wall of the gate electrode layer; and etching the exposed second conductive layer, the dielectric layer, and the first conductive layer to form a gate pattern.

The protective layer preferably is formed of a dual layer including a nitride layer and an oxide layer. The nitride layer preferably has a thickness of 20 Å to 100 Å and the oxide layer preferably has a thickness of 20 Å to 150 Å.

The method also may further include forming a hard mask pattern after forming the gate electrode layer.

The first conductive layer and the second conductive layer preferably are formed of a polysilicon layer, and the dielectric layer preferably has an ONO structure consisting of a first oxide layer, a nitride layer, and a second oxide layer.

The gate electrode layer is preferably formed from tungsten (W).

Another embodiment of the disclosed method includes forming a tunnel insulating layer, a first conductive layer, a dielectric layer, a second conductive layer, a gate electrode layer, and a hard mask pattern on a semiconductor substrate; performing an etching process using the hard mask pattern to pattern the gate electrode layer; forming a first protective layer on a side wall of the patterned gate electrode layer sufficient to prevent oxidation of the gate electrode layer and penetration of hydrogen ions to the gate electrode layer; forming a second protective layer on a surface of the first protective layer to prevent etching damage to the first protective layer during a process for etching the dielectric layer; and etching the exposed second conductive layer, the dielectric layer, and the first conductive layer to form a gate pattern.

The first protective layer preferably is formed of a nitride layer, and the second protective layer preferably is formed of an oxide layer.

The first protective layer preferably has a thickness of 20 Å to 100 Å, and the second protective layer preferably has a thickness of 20 Å to 150 Å.

Additional features of the disclosed invention may become apparent to those skilled in the art from a review of the following detailed description, taken in conjunction with the drawings, and the appended claims.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a sectional view of a semiconductor device for illustrating method for manufacturing a semiconductor device according to a conventional art;

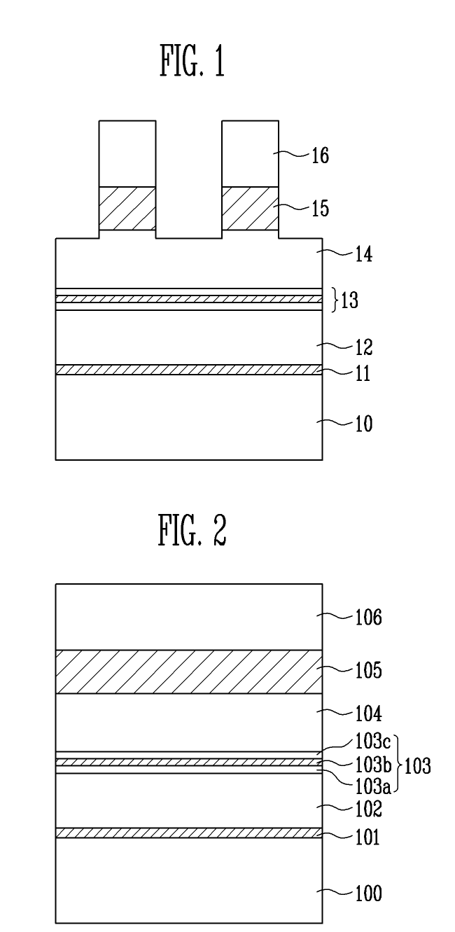

FIGS. 2, 3, 4, and 6 are sectional views of a semiconductor device that illustrate a method for manufacturing a semiconductor device according to one embodiment of the present invention;

FIG. 5A is a graph showing the oxidation degree of a tungsten layer relative to the thickness of a nitride layer; and,

FIG. 5B is a graph showing the penetration degree of a tungsten layer relative to the thickness of a nitride layer.

While the disclosed method is susceptible of embodiments in various forms, there are illustrated in the drawings (and will hereafter be described) specific embodiments of the invention, with the understanding that the disclosure is intended to be illustrative, and is not intended to limit the invention to the specific embodiments described and illustrated herein.

### DESCRIPTION OF SPECIFIC EMBODIMENTS

Hereinafter, the preferred embodiment of the present invention will be explained in more detail with reference to the accompanying drawings. It should be noted, however, that the following embodiments of the present invention may take different forms, and therefore, the scope of the present invention is not limited by the following embodiments of the present invention. The description herein is provided for illustrating the present invention more completely to those skilled in the art, and the scope of the present invention should be understood by the appended claims.

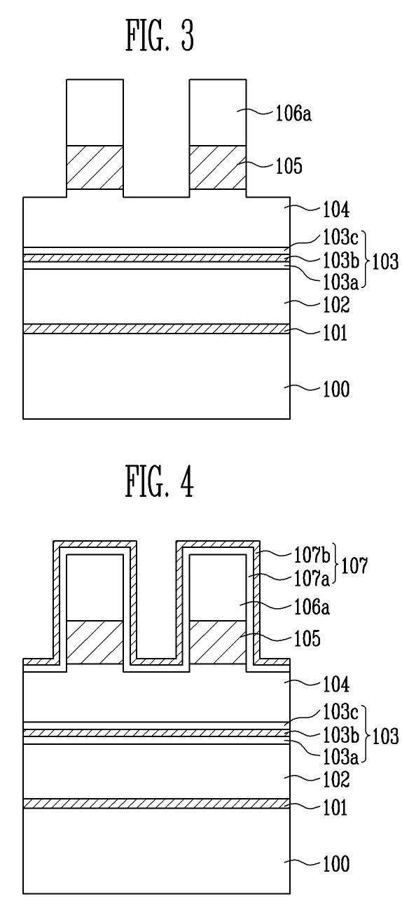

Referring to FIG. 2, a tunnel insulating layer 101, a conductive layer 102 for a floating gate, a dielectric layer 103, a conductive layer 104 for a control gate, a gate electrode layer 105, and a hard mask layer 106 are formed on a semiconductor substrate 100.

The conductive layers 102 and 104 may each be formed of a polysilicon layer. Preferably the dielectric layer 103 is formed in an ONO structure consisting of a first oxide layer 103a, a nitride layer 103b, and a second oxide layer 103c. Preferably, the gate electrode layer 105 is formed of a tungsten (W) layer.

Preferably the conductive layer 102 is formed of a dual layer consisting of an amorphous polysilicon layer, containing no impurities, and a polysilicon layer, containing impurities.

After the conductive layer 104 is formed, preferably a diffusion preventing layer (not shown) is formed prior to forming the gate electrode layer 105.

With continued reference to FIG. 2, a photoresist pattern is formed on the hard mask layer 106, and an etching process using the photoresist pattern is then carried out (i.e., the hard mask layer is patterned) to form hard mask patterns 106A as shown in FIG. 3.

Thereafter, an etching process, in which the hard mask pattern 106A is used as an etching mask, is performed to pattern the gate electrode layer 105. Preferably the etching process is performed to expose an upper portion of the conductive layer 104.

Referring to FIG. 4, a protective layer 107 is formed on the resulting, overall structure, including the patterned gate electrode layer 105 and the hard mask pattern 106A. The protective 107 may be formed of a single layer consisting of only nitride layer. Preferably, however, the protective layer is formed of a dual layer consisting of a nitride layer 107A and an oxide layer 107B.

Preferably the nitride layer 107A has a thickness of 20 Å to 100 Å, and the oxide layer 107B has a thickness of 20 Å to 150 Å.

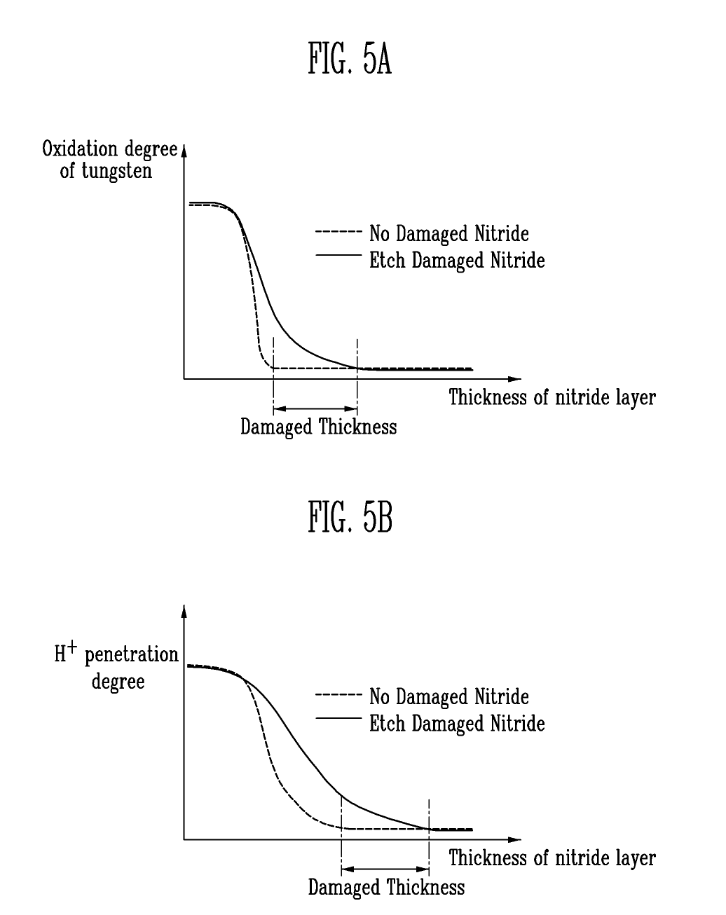

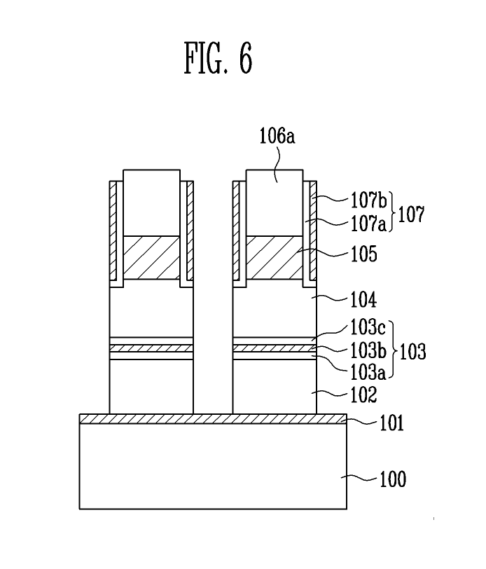

FIG. 5A and FIG. 5B are graphs showing variations of an oxidation degree and an infiltration (penetration) degree of a tungsten layer relative to the thickness of the nitride layer.

Referring to FIGS. 5A and 5B, where the protective layer 107 is formed of a nitride layer, the nitride layer should be formed with a certain minimum thickness to prevent oxidation of the gate oxide layer (tungsten) and penetration of hydrogen ions (H⁺) in a subsequent thermal process. Additionally, because an etching selection ratio between the nitride layer and the dielectric layer is large, the nitride layer may become damaged during a subsequent process for etching the dielectric layer 103. To prevent such damage, the thickness of the nitride layer should be increased. Increased thickness of the nitride layer reduces the distance between the gate patterns, which can reduce the integrity of the device. To solve the above phenomenon, as shown in FIG. 4, the protective layer 107 preferably is formed of a dual layer consisting of the nitride layer 107A and the oxide layer 107B. The oxide layer 107B can prevent etching damage to the nitride layer 107A, while maintaining the thickness of the nitride layer 107A.

Referring to FIG. 6, an etching process is carried out to remove selected portions of the protective layer 107 formed on the mask pattern 106A and the conductive layer 104. This etching process, however, does not remove those portions of the protective layer 107 present on side walls of the gate electrode layer 105.

Thereafter, the exposed conductive layer 104 for a control gate, the dielectric layer 103, and the conductive layer 101 for a floating gate are etched to form gate patterns of the semiconductor device.

According to one embodiment of the disclosed gate pattern forming process, after patterning the gate electrode layer, exposed surfaces of the gate electrode layer (i.e., side walls of the gate electrode layer) are surrounded with the protective layer. It is therefore possible to prevent the gate electrode layer from being oxidized during subsequent thermal, cleaning, and etching processes.

Additionally, because the protective layer is formed as the dual layer (consisting of the nitride layer and the oxide layer), it is possible to prevent the protective layer from being damaged during a subsequent process for etching the dielectric layer.

The foregoing description is given for clearness of understanding only, and no unnecessary limitations should be understood therefrom, as modifications within the scope of the invention may be apparent to those having ordinary skill in the art.

What is claimed is:

1. A semiconductor device comprising:
a tunnel insulating layer, a conductive layer for a floating gate, a dielectric layer, a conductive layer for a control gate and a gate electrode layer formed on a semiconductor substrate; and
a protective layer formed on a side wall of the gate electrode layer.

2. The semiconductor device of claim 1, wherein the protective layer comprises a nitride layer.

3. The semiconductor device of claim 1, wherein the protective layer further comprises an oxide layer.

4. The semiconductor device of claim 3, wherein the nitride layer has a thickness of 20 Å to 100 Å.

5. The semiconductor device of claim 3, wherein the oxide layer has a thickness of 20 Å to 150 Å.

6. The semiconductor device of claim 1, wherein the gate electrode layer is formed from tungsten (W).

7. A method for manufacturing a semiconductor device, the method comprising:
forming a tunnel insulating layer, a first conductive layer, a dielectric layer, a second conductive layer, and a gate electrode layer on a semiconductor substrate;
patterning the gate electrode layer to expose the second conductive layer;
forming a protective layer on a side wall of the gate electrode layer; and
etching the exposed second conductive layer, the dielectric layer, and the first conductive layer to form a gate pattern.

8. The method of claim 7, wherein the protective layer comprises a nitride layer and an oxide layer.

9. The method of claim 8, wherein the nitride layer has a thickness of 20 Å to 100 Å.

10. The method of claim 8, wherein the oxide layer has a thickness of 20 Å to 150 Å.

11. The method of claim 7, further comprising forming a hard mask pattern after forming the gate electrode layer.

12. The method of claim 7, wherein the first conductive layer and the second conductive layer are each formed of a polysilicon layer.

13. The method of claim 7, wherein the dielectric layer has an ONO structure consisting of a first oxide layer, a nitride layer, and a second oxide layer.

14. The method of claim 7, wherein the gate electrode layer comprises tungsten (W).

15. A method for manufacturing a semiconductor device, the method comprising:
forming a tunnel insulating layer, a first conductive layer, a dielectric layer, a second conductive layer, a gate electrode layer, and a hard mask pattern on a semiconductor substrate;
performing an etching process using the hard mask pattern to pattern the gate electrode layer;
forming a first protective layer on a side wall of the patterned gate electrode layer sufficient to prevent oxidation of the gate electrode layer and penetration of hydrogen ions into the gate electrode layer;
forming a second protective layer on a surface of the first protective layer to prevent etching damage to the first protective layer during a process for etching the dielectric layer; and
etching the exposed second conductive layer, the dielectric layer, and the first conductive layer to form a gate pattern.

16. The method of claim 15, wherein the first protective layer is formed of a nitride layer.

17. The method of claim 15, wherein the second protective layer is formed of an oxide layer.

18. The method of claim 15, wherein the first protective layer has a thickness of 20 Å to 100 Å.

19. The method of claim 15, wherein the second protective layer has a thickness of 20 Å to 150 Å.
